(19) United States
(12) Patent Application Publication
(10) Pub. No.: US 2021/0289655 A1
(43) Pub. Date: Sep. 16, 2021

(54) POWER CONVERTER FOR HIGH-POWER DENSITY

(71) Applicants: Eduardo Valdes, Conshohocken, PA (US); Raul Alvarado, Conshohocken, PA (US)

(72) Inventors: Eduardo Valdes, Conshohocken, PA (US); Raul Alvarado, Conshohocken, PA (US)

(21) Appl. No.: 17/202,274

(22) Filed: Mar. 15, 2021

Related U.S. Application Data
(60) Provisional application No. 62/989,253, filed on Mar. 13, 2020.

(51) Int. Cl. H05K 7/20; H02M 3/00; H02M 3/335

(52) U.S. Cl. CPC H05K 7/209; H02M 3/33569; H02M 3/01

(57) ABSTRACT

The present invention provides for a high-density power converter that uses high frequency switching, and improved heat transfer capabilities, thus optimizing heat removal to provide a higher efficiency, lighter, and smaller form factor power converter with increased specific power and power density, and is capable of handling high power and high frequency operation. Embodiments of the invention employ novel approaches for the driving circuit design, planar magnetics design, thermal management solution design, and manufacturing techniques to solve the unmet need for a power converter utilizing high frequency switching circuits along with improved heat transfer from the switching circuits, while to providing improved methods for heat transfer from power converters to allow for more compact form factors and higher specific power and power density.

### CROSS-REFERENCE TO RELATED APPLICATIONS

This application claims the benefit of U.S. Provisional Application No. 62/989,253, having a filing date of Mar. 13, 2020, the disclosure of which is hereby incorporated by reference in its entirety and all commonly owned.

### FIELD OF INVENTION

The present invention provides for an improved power converter. More particularly, the present invention provides for improved power converters incorporating a thermal management solution allowing for high specific power, high power density and high efficiency.

### BACKGROUND

Power converters are widely used across all industries were power conversion is required, including without limit, solar energy, electric vehicles, airplanes, satellites, servers, consumer electronics. However demand to achieve similar or better results at a much smaller size is constant. Smaller sizes and larger power capacity (and power density) are beneficial for various applications, and provide advanced capability, with a much smaller payload. As a non-limiting example, future space missions require satellites and space probes with higher power capacities while simultaneously reducing production and launching costs (mass, size, complexity).

In the commercial sector, there is an increased demand for more powerful satellites and the market for LEO satellites is quickly growing. However power converters used for these, and other applications, are limited in their specific power and power density, thus there remains an unmet need for power converters which allow for increased specific power and power density.

High-Power Density Converter technology can be utilized for satellites across multiple internal sub-systems including, but not limited to: PPU (Power Processing Unit), EPS (Electric Power System), PDU (Power Distribution Unit), and POLs (Point of Loads). The capabilities of a large satellite can be packed into a much smaller and cost-effective satellite/probe. A reduction in size and weight of critical sub-systems within the current payload volume of current satellites allows commercial satellite service providers to install more payloads, which yield higher revenues per year through an increase of service output per satellite. High-Power Density Converter technology can provide a development platform for next-gen high power space applications for future scientific, defense, and commercial missions and become an enabling technology that not only benefits the space industry but also earth-based industries such as military drones and ground vehicles.

Moreover, Future space missions will require satellites and space probes with higher power capacities while simultaneously reducing production and launching costs (mass, size, complexity). In the commercial sector, there is an increased demand for more powerful satellites and the market for LEO satellites is quickly growing.

Despite the needs of improved power converters for these purposes, little innovation and improvement has been accomplished in power converter performance and construction, there remains an unmet need for improved power converters to enable use for creating more powerful devices, such as satellites.

Few attempts have been made to improve power converters, but all fall short, usually requiring a larger form factor and increased weight. These larger devices are as a result of the heat transfer removal required for power converters which provide larger specific power and high power densities. Thus there remains an unmet need to provide improved methods for heat transfer from power converters to allow for more compact form factors and higher specific power and power density.

Moreover, switching circuits used in typical power converters typically operate at low frequencies, thus contributing to switching losses. These switching losses affect overall performance and reduce specific power and power density capacity for such devices. Attempts have been made at using different types of power transistors as switching circuits, but often the compact design, and increased heat flux as a result, has limited their incorporation. Thus there remains an unmet need for a power converter utilizing high frequency switching circuits along with improved heat transfer from the switching circuits.

Thus there exists an unmet need to address the above-stated problems to mitigate and/or obviate the aforementioned disadvantages of typical or conventional power converters.

### SUMMARY OF INVENTION

The present invention addresses the above-stated problems to mitigate and/or obviate the aforementioned disadvantages of the typical or conventional power converters. The technology described herein is a direct response to the current demand for high power converters that yield optimal SWaP-C (size, weight, power, cost) with an emphasis on power density.

The present invention provides for a high-density power converter that uses high frequency switching, and improved heat transfer capabilities, thus optimizing heat removal to provide a higher efficiency, lighter, and smaller form factor power converter with increased specific power and power density.

The present invention, as described herein, is capable of handling high power and high frequency operation. Custom designs using additive manufacturing (as used herein refers to 3-D printing technology) are used to build magnetic components to reduce size and improve performance (compared to conventional machined ferrite cores). Similarly, additive manufacturing is used for the construction of the thermal management solution (TMS).

In some embodiments, space-grade gallium nitride (GaN) power devices are used to reduce switching losses while operating at higher frequencies. Thus, reducing overall unit size and increasing efficiency.

Embodiments of the invention leverage and integrate two major technologies: additive manufacturing (for the development of the thermal management solution and optimized magnetic components) and space-grade GaN power devices.

Embodiments employ novel approaches for the driving circuit design, planar magnetics design, thermal management solution design, and manufacturing techniques.

### BRIEF DESCRIPTION OF THE DRAWINGS

Examples illustrative of embodiments of the disclosure are described below with reference to figures attached hereto. In the figures, identical structures, elements or parts that appear in more than one figure are generally labeled with the same numeral in all the figures in which they appear. Dimensions of components and features shown in the figures are generally chosen for convenience and clarity of presentation and are not necessarily shown to scale. Many of the figures presented are in the form of schematic illustrations and, as such, certain elements may be drawn as simplified or not-to-scale, for illustrative clarity. The figures are not intended to be production drawings. The figures (Figs.) are listed below.

FIG. 1 illustrates at least one embodiment of a prior art power converter circuit, particularly a LLC full bridge power converter.

FIG. 2 provides at least one embodiment of the inventive High-Power Density Converter's printed circuit board (PCB) in a “full-brick” form factor.

FIG. 3 provides at least one embodiment of the inventive High-Power Density Converter with TMS installed on a “full-brick” form factor.

FIG. 4 provides a top and bottom view of an assembled printed circuit board (PCBA) for at least one embodiment of the inventive High-Power Density Converter in a “half-brick” form factor.

FIG. 5 provides a cutaway side view 100 of at least one embodiment of a vapor chamber 20 formed from a wicking layer 40 that is mechanically and thermally coupled to an outer layer, a pre-fabricated radiator structure 10, a separately formed top portion 35 with an inner layer 40 including a continuous condenser 5, and a bottom portion 75 including an evaporator 95 that demonstrates the flow pattern of an encapsulated fluid, i.e. a coolant fluid such as water.

FIG. 6 provides a cutaway side view 100 of at least one embodiment of a vapor chamber 20 formed from a wicking layer 40 that is mechanically and thermally coupled to an outer layer, a pre-fabricated radiator structure 10, a separately formed top portion 35 with an inner layer 40 including a discontinuous condenser 5, and a bottom portion 75 including an evaporator 95 that demonstrates the flow pattern of an encapsulated fluid, i.e. a coolant fluid such as water.

FIG. 7 provides a cutaway end view 200 of a vapor chamber with a top finned radiator structure 10, a plurality of capillary pathways 60, a region comprising one or more fins 61, and a bottom portion 75.

FIG. 8 provides a cutaway top view of at least one embodiment of a 300 vapor chamber with a plurality of capillary pathways 60, an outer layer 30, a wicking layer 40 including regions 45, 25, 70, and 80, and a bottom portion 75 including an evaporator 95 that demonstrates the flow pattern of an encapsulated fluid, i.e. a coolant fluid such as water.

FIG. 9 provides a top view of at least one embodiment of a circuit board with TMS vapor chambers 410, 420, 430, and 440 and the exposed surface of a planar magnetic device 450 that is covered by a vapor chamber.

FIG. 10 provides a bottom view of at least one embodiment of a circuit board with TMS vapor chambers with uncovered devices 405 and 415 and the exposed surface of a planar magnetic device 450 that is covered by a vapor chamber.

FIG. 11 provides a side view of at least one embodiment of a circuit board with TMS vapor chambers 410, 430, and 440, a planar magnetic device 450, and demonstrates variability in component shapes and chassis illustrating 412 one or more cavities that can be filled using AM, and 414 one or more protrusions that can be modified using AM).

FIG. 12 provides a cutaway side view of at least one embodiment of the omni-directional and uni-lateral thermal circuit of a vapor chamber formed from a TMS using additive manufacturing (allowing customized and optimized fluid flow channels that conform the to the geometric and thermal needs of the PCBA) with the vapor chamber making use of prefabricated wicking structures (mesh, foams, sintered powder) to provide passive capillary liquid flow.

FIG. 13 provides a cutaway side view of at least one embodiment of a TMS using additive manufacturing that demonstrates how a vapor chamber “wraps” around the components as much as possible, thereby providing adequate thermal management.

FIG. 14 provides alternate views of at least one embodiment of micro pins that may be used to build capillary pathways, with the micro pin printed.

FIG. 15 demonstrates at least one embodiment of the TMS running, the TMS consisting of a single input, dual-path, dual-loop thermal circuit topology with independent cooling blocks that reduce temperature differences between component sets. The simulations show fluid flow and heat sinking to be adequate to maintain optimal operating temperatures at the highest simulated heat losses.

FIG. 16 provides at least one embodiment of a CFD thermofluidic simulation single input that also demonstrates how the TMS serves as the enclosure of the unit through the presented design that reduces the number of assembly steps by integrating the TMS and enclosure into a single unit using additive manufacturing.

It should be clear that the description of the embodiments and attached Figures set forth in this specification serves only for a better understanding of the invention, without limiting its scope. It should also be clear that a person skilled in the art, after reading the present specification could make adjustments or amendments to the attached Figures and above described embodiments that would still be covered by the present invention.

### DETAILED DESCRIPTION

The present invention provides for one or more embodiments of an inventive power converter. Inventive embodiments include a modular isolated dc-dc power converter that achieves high Specific Power, Power Density, and high efficiency levels. In no way intending to limit the present invention to any minimum or maximum Specific Power, Power Density, or efficiency, embodiments of the present invention have shown to exhibit Specific Power greater than 20 kW/kg, a Power Density greater than 30 W/cm3 at efficiency levels greater than 95%.

Embodiments of the invention, as described herein, rely on three technical pillars: Gallium Nitride power transistor (GaN), Additive Manufacturing (AM) of the Thermal Management Solution (TMS), and On-Demand Magnetics. Aspects of the invention provide for any form factor desirable. It should be appreciated that embodiments herein can be configured for any form factor known in the art, or which may otherwise be developed for any use. Without being bound to any particular form factor, certain embodiments include a Distributed-power Open Standards Alliance (DOSA) “half-brick” or “full-brick” form factor. Likewise, and without limiting the present invention, form factors used may further be any VERSA-module Europe (VME) International Trade Association (VITA) form factor.

The following detailed description is exemplary in nature and is in no way intended to limit the scope of the invention, its application, or uses, which may vary. The invention is described with relation to the non-limiting definitions and terminology included herein. These definitions and terminology are not designed to function as a limitation on the scope or practice of the invention, but are presented for illustrative and descriptive purposes only.

### General

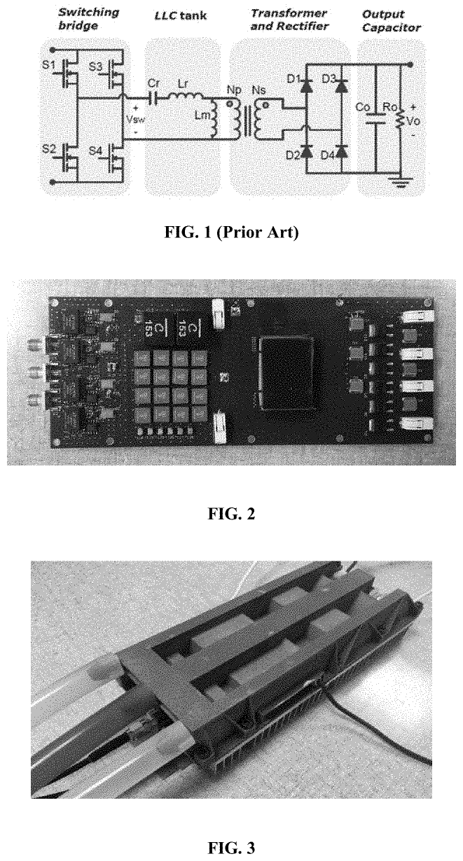

The present invention provides for a modular isolated power converter. Embodiments of inventive power converters described herein include, but are not limited to, LLC (inductor-inductor-capacitor) power converter circuits including at least one switching bridge, an LLC tank circuit, and at least one transformer and rectifier circuit. FIG. 1 provides for a typical LLC type circuit known in the art. In addition embodiments of inventive power converters as described herein include at least one thermal management solution (TMS) mounted to one or more components of the LLC power converter circuit. It should be appreciated that in embodiments of the invention described herein, the TMS is mounted to one or more components of the LLC power converter circuit for removal of heat generated by the LLC power converter circuit while in operation. Without limiting the maximum specific power and power density achievable by using the devices and methods described herein, at least one embodiment described herein allow for isolated dc-dc power converter that achieves a Specific Power greater than 20 kW/kg, a Power Density greater than 30 W/cm³ at efficiency levels greater than 95%.

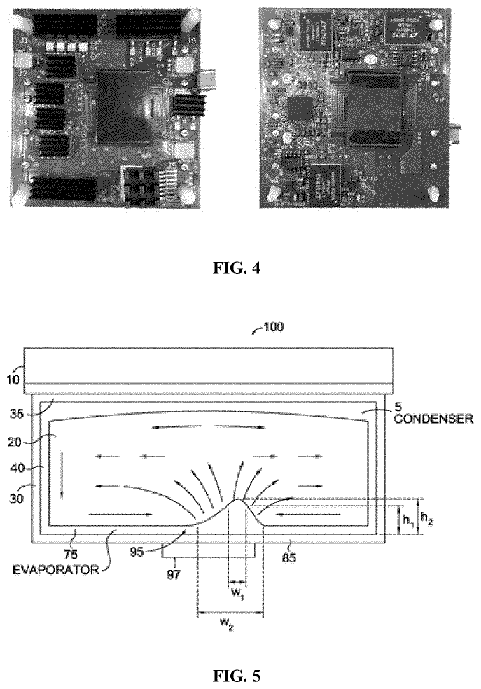

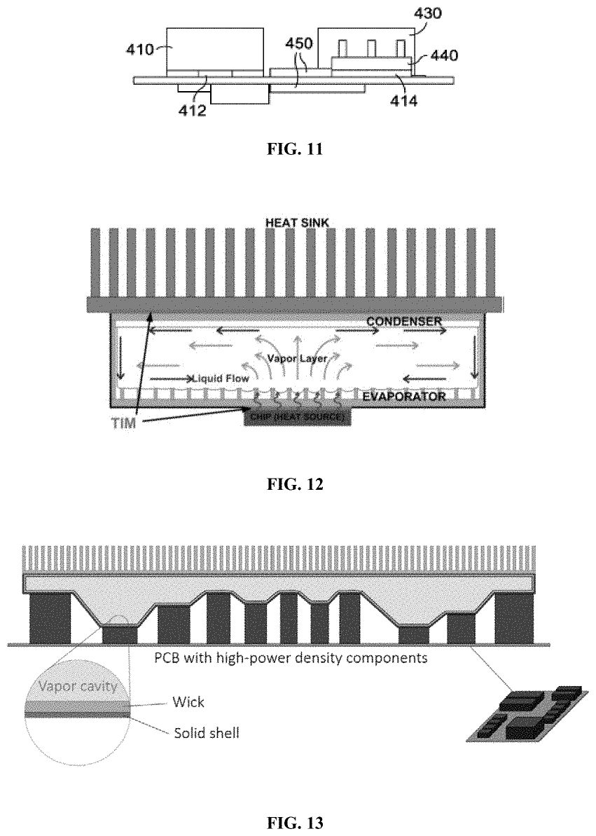

Some representative structures of a high power device are depicted in FIG. 4 and similar representative structures are depicted in FIGS. 9, 10 and 11. A high power device in at least one embodiment is a high power converter device that comprises a circuit board. A circuit board including components 97 such as a planar magnetic device 450, a GAN device, and an inductive device that are served by one or more TMS vapor chambers is shown in top view in the left hand side of FIG. 4 and in a bottom view in the left hand side of FIG. 4. Likewise, a circuit board with a TMS vapor chamber is shown in top view in FIG. 9, in bottom view in FIG. 10 and in side view in FIG. 11. FIG. 4 shows in the portion to the left, a top view of a circuit board with various components covered by vapor chambers. FIG. 9 shows vapor chambers 410, 420, 430 and 440. In the left portion of FIG. 4 a planar magnetic device is exposed, but In at least one embodiment this surface of a planar magnetic device is covered at least in part by a vapor chamber. In FIG. 9 and FIG. 10 planar magnetic device 450 likewise is exposed, but in at least one embodiment the exposed surface of 450 shown in FIG. 9 is covered by a vapor chamber. FIG. 4 shows in the portion to the right, a bottom view of a circuit board with various components uncovered. FIG. 10 shows uncovered devices 405 and 415. FIG. 11 shows a side view of a circuit-board incorporating improved vapor chambers.

At least one embodiment of a high power electronic device comprises at least one of (a planar magnetic device, a GAN device, and an inductive device) protected by a chamber of a TMS comprising vapor a chamber 20 having a plurality of capillary pathways 60, wherein a pair of the capillary pathways form the sides of a substantially trapezoidal nonrectangular region in a direction of capillary flow, wherein the plurality of capillary pathways conduct liquid to a customized destination region 70.

In at least one embodiment, the inventive high power device includes a wide-range GaN Based High Density Power Converter using Additive Manufacturing. The technology is a power conversion unit that can be used across a wide range of applications. The unit integrates three main components/technologies: Gallium Nitride (GaN), thermal management solution (TMS) and planar magnetics. In at least one embodiment, either TMS or planar magnetics are manufactured using additive manufacturing utilizing materials such as aluminum and/or copper (for the thermal management) and magnetic material (for the planar magnetics).

In at least one embodiment, a device has increased the power density. It should be appreciated that GaN allows a design to increase frequency of operation, which leads to smaller components. In some embodiments, additive manufacturing may be incorporated to design TMS capable of quickly redirecting heat from high density loss sources. Without being bound to any particular theory, it is believed that additive manufacturing allows for a novel planar magnetics design that can be optimized for size and efficiency at high frequencies and high-power operation. Embodiments constructed as described herein with integrating thermal management and planar magnetics improve the capabilities of GaN.

In at least one embodiment, a High density converter converts voltage from one level to another (i.e. 120V input, 300V output) providing isolation (transformer). This is achieved by the switching ON/OFF of the “primary” switches, which excites the resonant tank that is comprised of an inductor, a capacitor, and the transformer. The current generated on the primary side creates a magnetic flux, which induces a current on the secondary side of the transformer. At the secondary side, the sine wave is rectified, producing a DC voltage with amplitude equal to the turns ratio of transformer plus any voltage multiplication on the rectifier, if any. In the explanation above, the switches on the primary are the GaN HEMTs. The frequency at which they are switched is 1 MHz or above.

In at least one embodiment, a successful design (high efficiency) considers the following criteria: Dead time: Amount of time at which all primary switches are ALL off; Magnetizing inductance: Minimum value required such that GaNs achieve ZVS condition; Gain: The LLC uses frequency modulation to regulate output voltage. There is a gain profile that is determined by the combination of the dead time, the magnetizing inductance, the turns ratio of the transformer, and the power level. All of these values are swept until an ideal value is determined. It should be appreciated that the tradeoffs between high voltage gain vs efficiency (high gain leads to high circulating current through the resonant tank. High voltage gain leads to wide range capability for the converter. In at least one embodiment, each component provides a successful unit: GaN is a semiconductor that is used as a switch, operated at high frequency. GaN has low losses inherently (if used appropriately); GaN Gate Drivers are required to operate the GaNs properly. They require proper layout; Magnetic components: Typically the bulkiest components in the converter. High frequency at high power levels (i.e. high current) can be challenging. The converter requires magnetic components that can operate at this frequency (>1 MHz) which is not industry standard. In at least one embodiment, a custom design uses conventional cores off the shelf, as well as novel geometries using additive manufacturing; Thermal management: In at least one embodiment, once the electrical part has been tuned and components have been selected and designed (along with proper board layout), the thermal management is placed on top, “wrapping” around all high power components. The TMS allows the operation of the unit at a specific ambient temperature set by the application. It allows the unit to run at a safe temperature. In at least one embodiment, additive manufacturing for the TMS is provided.

### GAN Power Transistor

In certain embodiments of the inventive power converter, at least one switching bridge is at least one power transistor. In at least one embodiment, the power transistor is a Gallium Nitride power transistor (GaN).

Embodiments of the inventive power converter use GaN power transistors to increase the frequency of operation to yield a more compact unit. GaN power transistors have low on-state losses, high voltage capability, high frequency switching, and high temperature operation. FIG. 2 shows that, in embodiments of the invention described herein, the GaN power transistors yield higher power density (low SWaP).

Although the use of GaN power transistors results in a more compact unit, the drastic decrease in overall size results in significantly increased and non-uniform heat flux. Non-uniform heat flux across the die surface results in power-dense regions that can produce hot spots, regions where local temperature is significantly higher than the die average temperature. The overall reliability of power converters using GaN power transistors is determined by the hottest region on the die rather than the average die temperature, which necessitates a thermal management design that with an enhanced, efficient heat spreading capability at both the ‘local’ single transistor device level as well as at the ‘global’ die and packaging levels.

In at least one embodiment, a high power board is laid out with a GaN HEMT to minimize inductance parasitics (to reduce overshoot at the gate terminals—hence keep driving signal less than 5V). Proper board layout also aids to spread the heat and prevent component overheat. The thermal challenge is fully addressed with a proper thermal management system design. A GaN power device, e.g. a freebird device, is a semiconductor component that is used as a switch. This switch is part of a “switching power converter.” The GaN power device is switched at a frequency determined by the designer. The presented technology operates at 1 MHz or above (this frequency is considered relatively high within the power conversion industry give the power level). The power conversion unit is utilized for different purposes: regulate bus voltage, isolation, up-convert/down-convert bus voltage.

In at least one embodiment, a high power device includes a GaN Gate driver. A GaN-based gate driver capable of driving GaN HEMTs. In at least one embodiment, a gate driver keeps the driving signal between 0V and 5V and capable of switching up to 3 MHz. The GaN Gate Driver must be kept as close as possible to the GaN HEMTs. This ensures no overshoot at the gate terminals of the GaN HEMTs. The GaN Gate Driver is used to switch the GaN HEMTs on and off. In at least one embodiment, the gate driver is operational with space-grade performance.

GaNs are switched with a center frequency of 1 MHz (as an example) with a bandwidth of 200 kHz (for example, varies by application). A unit can operate at wide input voltage range (68-148V) and wide output voltage range (200-700V). A unit is kept at temperatures below 50 degrees C. The latter heavily depends on ambient temperature for a specific application. The TMS is designed to match the application requirement.

### Thermal Management System

In certain embodiments of the inventive power converter, at least one TMS including a vapor chamber is mounted to one or more components of the LLC power converter circuit for removal of heat generated by the LLC power converter circuit while in operation.

In at least one embodiment, the vapor chamber includes a top finned radiator structure 10 and a case chamber 20. The case chamber includes an outer layer 30 that is physically and thermally coupled through a top surface of a top portion 35 of the outer layer 30 to said finned radiator structure 10, wherein a bottom surface of a bottom portion 85 of the outer layer is physically and thermally coupleable to at least a first heat source component 97. The case chamber also includes an inner wicking layer 40 that is physically and thermally coupled to the outer layer 30, a bottom portion 75 of an inner wicking layer 40 including a 60 plurality of capillary pathways, and a pair of the capillary pathways forming the sides of a substantially trapezoidal nonrectangular region in a direction of capillary flow, wherein the plurality of capillary pathways conduct liquid to a designated customized region 70.

In at least one embodiment, a region comprises a region with one or more fins, such as those fins 61 shown in profile in FIG. 7, or in top view FIG. 4, or illustrated in FIG. 7. In at least one embodiment, each fin (e.g. from fins 61) midway between capillary pathways 60 forms the sides of a channel, groove, or pathway that provides a capillary pathway 60. Each pair of fins forms the sides of a substantially trapezoidal nonrectangular region in a direction of capillary flow. Non-uniform spacing of fins is illustrated for example in bottom portion 75 of inner layer 40 having pathways 60 and in at least one embodiment fins 61. In at least one embodiment, a sequence of trapezoid shaped regions lacking the top and bottom portion form the sides of a channel to form a pool intervening between a pair of adjacent fins.

Representative structures of a vapor chamber are depicted by FIGS. 5, 6, 7 and 8 in cutaway side view 100, in cutaway end view 200 and in cutaway top view 300.

Embodiments of an improved vapor chamber 100 consist macroscopically of a top finned radiator structure 10 that is coupled to a case chamber 20. In at least one embodiment, radiator structure 10 is pre-fabricated. In at least one embodiment, the top portion 35 of outer layer 30 is separately formed using additive manufacture by incorporating top layer 35 and condenser 5 onto the radiator structure 10 and then physically coupling the combined structure to the remaining, separately formed portion of vapor chamber 20 to form a hermetically sealed fluid containing chamber. In at least one embodiment, layer 30 forms a six-sided case that provides structural integrity and heat conduction capabilities. In at least one embodiment, a lower surface of bottom layer 85 is coupled to an electrical component 97 such as a GAN chip, a voided AIN cavity, an inductor, a planar magnetic component. A top portion 35 of outer layer 30 is mechanically and thermally coupled to radiator structure 10. An inner wicking layer 40 is mechanically and thermally coupled to outer layer 30. In at least one embodiment, wicking layer 30 comprises a region such as region 45, 25, 70 or 80 that forms a wicking layer comprising a mesh pattern, a foam pattern, or a sintered powder, providing capillary liquid flow. In at least one embodiment, a layer is formed of copper. In at least one embodiment, a layer is formed of aluminum. An encapsulated fluid, i.e. a coolant fluid such as water, flows in the pattern shown in FIG. 5, 5. A bottom portion 75 includes an evaporator 95, and top portion of inner layer 40 includes a condenser 5. In at least one embodiment, condenser 5 forms a taper shown in FIG. 5, 5 thus drawing condensed liquid to the sides of vapor chamber 20.

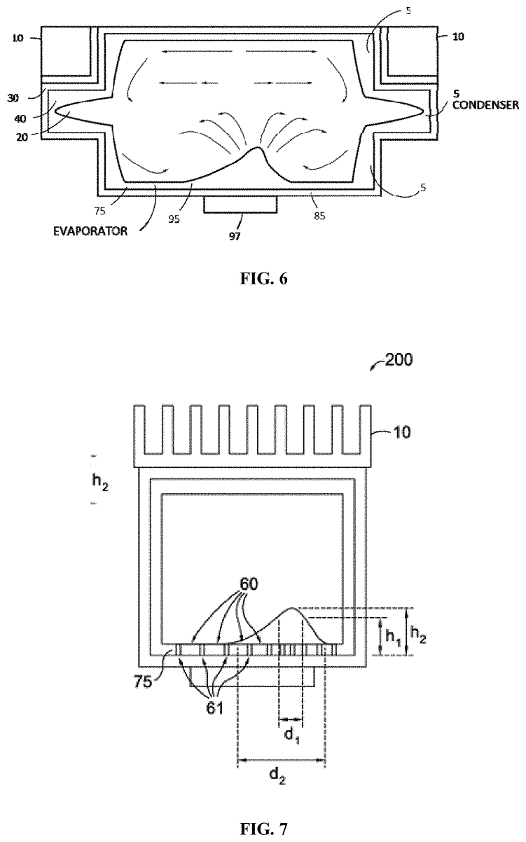

Embodiments of the present invention may include a continuous condenser, or a discontinuous condenser. FIG. 5 illustrates at least one embodiment of the present invention using a continuous condenser. FIG. 6 illustrates at least one embodiment of the present invention using a discontinuous condenser.

It should be appreciated that heat pipes and vapor chambers traditionally have a thermal “input” (evaporator) and “output” (condenser) with an interim fluid transport & vapor flow region (adiabatic section). All two-phase thermal transport devices require these three sections for effective heat transfer and/or dissipation. In traditional heat pipes and vapor chambers, the evaporator to condenser can have equal surface areas, and therefore exhibit a one-to-one surface ratio. In addition, the thermal transfer regions are designed as unbroken surface areas, providing a simple thermal transfer loop.

Unlike heat pipes, vapor chambers have much larger evaporator and condensers regions. In standard PCB assemblies, multiple heat generating components can be bonded to the evaporator region. This creates a rather complex thermal transfer loop. However, this thermal transfer loop can still be modelled as a singular loop from a single evaporator region to a single condenser region.

Where used, a discontinuous condenser, versus a continuous condenser enables a new dynamic model of thermal transfer and dissipation. A discontinuous condenser requires the condenser region of a vapor chamber to be broken up into multiple interrupted “cold” regions that are separated by multiple adiabatic regions. A vapor chamber with a discontinuous condenser operates with multiple internal thermal transfer loops that operate in parallel. The condenser regions possess internal radiator-like thin-wall structures that increase the condenser's total heat transfer surface areas. This highly complex dynamic system is made possible through additive manufacturing. Without additive manufacturing, the ratio between the total condenser region(s) and evaporator region could not reach a minimum of one-to-one.

In at least one embodiment, a discontinuous condenser region can be integrated into assemblies where large and unbroken surfaces are uncommon. These discontinuous surfaces do not have to be thermally synchronized. These surfaces can also be implemented in any orientation with the appropriate wicking structures. This enables the implementation of two-phase thermal management in applications where design flexibility is limited by form factor and packaging density requirements. As a non-limiting example, VITA-based power conditioning modules depend heavily on conduction-based cooling. This conduction cooling architecture provides thermal transfer through two parallel thermal rails. Through the application of a discontinuous condenser region, these cooling rails can be utilized as condenser regions using SET group's discontinuous condenser architecture, whereas a traditional vapor chamber would be difficult to integrate and would not provide adequate thermal performance.

In at least one embodiment, physical coupling is achieved by one or more of additive manufacturing, iterative formation, welding, Metal Inert Gas (MIG)/Metal Active Gas (MAG) welding, brazing, soldering, pressure connection, and joining. In at least one embodiment, iterative formation builds up a structure on a side of a finished piece, at a selected formation angle. In at least one embodiment, physical and thermal coupling is formed by a Thermocouple Input Module (TIM). In at least one embodiment, iterative formation is performed by milling. In at least one embodiment, iterative formation includes eroding or building a surface with one or more of an acid wash, a base wash, a salt wash, and an anodizing step.

A top cutaway view 300 of bottom portion 75 of inner layer 40 is shown in FIG. 10. In at least one embodiment, a region 70, and a region 80 are customized. In at least one embodiment, a region has increased surface area. In at least one embodiment, a region has increased surface area formed by the height of a varied surface area pattern. For example, a hot spot region is present on the surface of device 97 directly beneath region 80. In at least one embodiment, the shape shown in FIG. 10 shows the shape of a highest isothermal contour in the boundary of region 80, and a lower isothermal contour in the boundary of region 70. A region 25 is the region directly over device 97 but outside of region 70. A region 45 represents the wicking layer outside of region 25. The embodiment depicted in FIGS. 5-8 show an increased surface area of a region at least in part by raising the height of a region into a ridge. A ridge formed in wicking layer 40 rises to a height h2 above outer layer 30. In region 70 the height of wicking layer 30 rises from a nominal thickness for inner layer 40 to a height h1 at the boundary to region 80. Region 70 has depth d2 and width w2. Region 80 has depth d1 and width w1. A side cutaway view of chamber 20 shows evenly spaced fins in radiator structure 10.

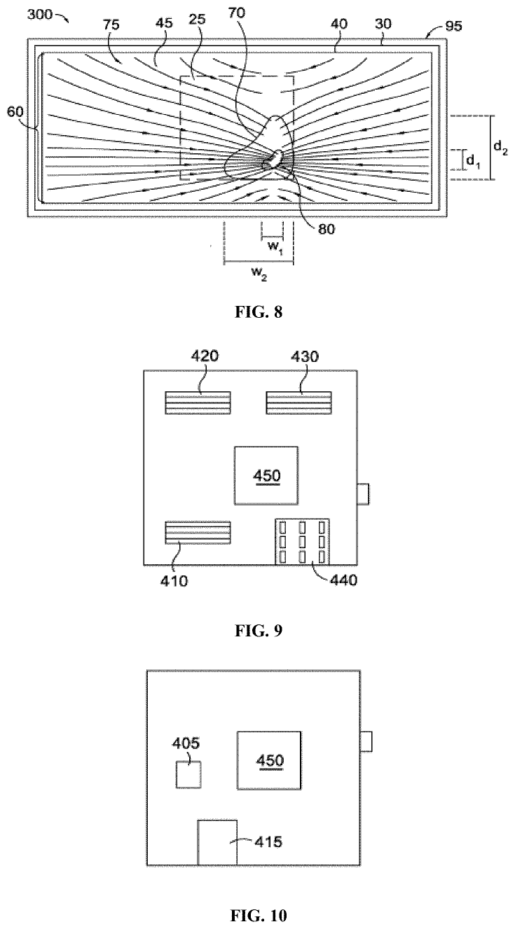

In at least one embodiment, a region increases the surface area by varying the material construction pattern. For example, a region 45 is designed primarily with fins forming pathways as shown in FIG. 8, a region 25 is a mixture of porous fins of increased surface area, and intervening mesh or foam. A region 70 is a mixture of higher porous fins and increased height of porous foam. A region 80 is a highest surface area channelized foam with the channels directing vapor in the vertical direction to the evaporator 5. An outer layer 30 is physically and thermally coupled through a top surface of a top portion 35 of the outer layer 30 to the finned radiator structure 10. A bottom surface of a bottom portion 85 of the outer layer 30 is physically and thermally coupleable to at least a first heat source, such as device 97. An inner wicking layer 40 is physically and thermally coupled to the outer layer 30. A bottom portion 75 of an inner wicking layer 40 is comprised of regions depicted in FIG. 8 including adjacent regions 80, 70, 25 and 45. In at least one embodiment, region 80 covers a hottest-spot, and region 70 covers a region that forms a next-hottest region. A region 25 is the portion outside of region 70 that is generally over electronic device 97. In the embodiment shown in FIGS. 5-8 the increased surface area is shown as a ridge that reaches a peak in region 80. In at least one embodiment, the customized region forms a valley that reaches a minimum in region 80. In at least one embodiment, a plurality of capillary pathways 60 conducts liquid, e.g. from the outer portion of layer 75 of FIG. 8 to a region 70. In at least one embodiment, adjacent pathways in the plurality of pathways 60 are separated by a ridge that forms a boundary between two adjacent paths. In at least one embodiment, a pathway is formed by adjacent ridges that form an intervening trough to provide a pathway. In at least one embodiment, a pathway in the plurality of pathways 60 forms a liquid pool near to an outside edge of vapor chamber 20 and the pool gradually narrows as a pathway proceeds toward a region 70. Individual paths within the plurality of pathways 60 are generally linear. Arrows are included on pathways 60 to show the direction of capillary fluid flow.

A pair of the capillary pathways 60 forms substantially the sides of a nonrectangular trapezoidal region, wherein the plurality of capillary pathways conduct liquid to a designated customized region, e.g. region 70. Sides from a pair of pathways shown in FIG. 8 form the sides of a substantially trapezoid-shaped region formed by a course of flow are nonrectangular, meaning that over their coarse from an exterior edge to a region 70 the edges of a pathway do not form rectangular sides over their course. For example, the two pathways closest to the right hand side of FIG. 8 form substantially a rhombus shape over their course, notwithstanding the fact that as shown in FIG. 4 the micro pins are laid down on a case by case basis within a rectangular grid. The pathways over their course drift to the left forming a rhombus in a portion of the path from the outer edge to a region 70. Similarly, when a rightmost pathway and a leftmost pathway are chosen as a pair that traverses from an edge to region 70 through a vertical path looking at FIG. 8, each path drifts toward the other path as the paths traverse the path from an outer edge to a region 70. A pathway shown in FIG. 8 at times forms a portion of a concave up arc over a course from the edge to a region 70. In at least one embodiment, a pathway in pathways 60 macroscopically follows instead a portion of a concave down arc, or an “S” shaped arc. In at least one embodiment, a ridge defining a boundary to a pathway follows a path that is generally perpendicular to an isothermic contour.

In at least one embodiment, a Thermal Management Solution (TMS) uses Additive Manufacturing (AM). A TMS is the unit that maintains the temperature of the power converter within limits set by the designer. In at least one embodiment, a TMS is built using AM as the process for fabrication. Copper and aluminum have been used as the material of the TMS (other materials that are high conductive can also be utilized). The design consists of a vapor chamber. A vapor chamber relies on custom or prefabricated wicking structures (mesh, foams, sintered powder) to provide passive capillary liquid flow. Additive manufacturing allows for customized and optimized fluid flow channels that conform to the geometric and thermal needs of the Printed Circuit Board (PCB). This can concentrate capillary action towards high heat zone areas in order to best distribute the evaporator heat flux capacity and to reduce the possibility of capillary pump breakdown.

In at least one embodiment, a TMS integrates both the cooling structure and the mechanical structure into a single unit. This results in less number of components.

Developing an additive manufacturing TMS with novel geometries (i.e. vapor chamber) may involve trial and error. In at least one embodiment, a TMS encompasses the geometry itself, but also a process to fabricate it. Additive Manufacturing has limitations, which means that not all geometries can be fabricated. The angle at which it is fabricated, for example, plays a role. The TMS ensures the power converter stays within the temperature boundaries set by the designer. The unit also serves as the mechanical housing. This may be mounted onto the system in which the unit is operating.

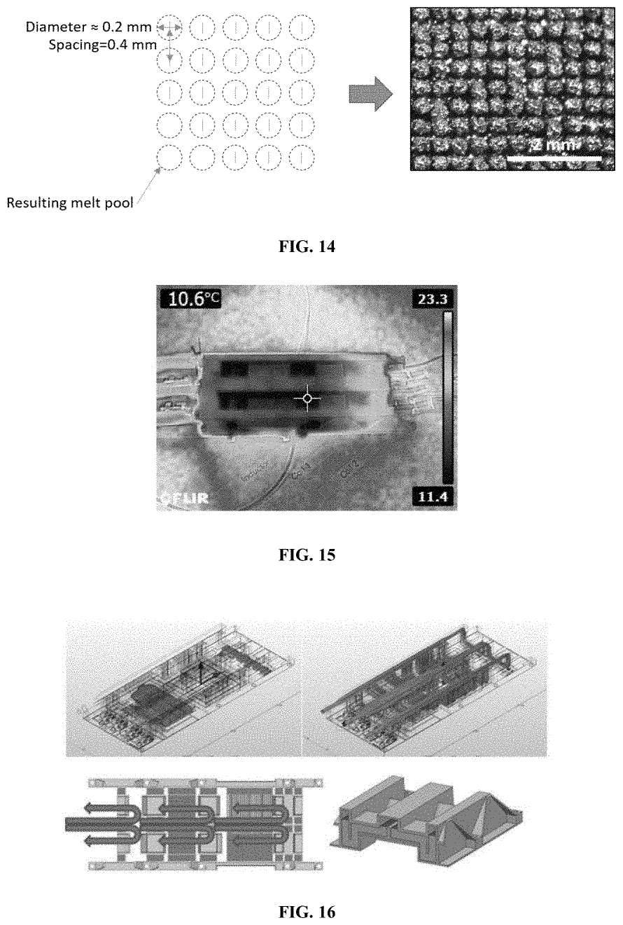

In at least one embodiment, a single vapor chamber “wraps” around the components as illustrated in FIG. 3 and provides adequate thermal management. The single vapor chamber is tuned using sintered channels in order to provide the maximum heat transfer from high heat flux areas of the PCB such as the series inductors and GaN devices. The capillary pathways include patterned/dense structures consisting of micro pins, grooves, and lattice structures. FIG. 14 shows at least one embodiment incorporating micro pins. In at least one embodiment micro pin spacing and size are printed with a diameter of 0.2 mm at 0.4 mm spacing.

### Planar Magnetics

In certain embodiments of the inventive power converter, at least one transformer and rectifier circuit includes at least one planar magnetic transformer.

It should be appreciated from an electronics design point of view, a critical component of any power converter is the transformer. Traditional transformers utilize a multi-piece ferrite core with wound copper wire to provide the adequate electrical characteristics. Unfortunately, in high power density applications thermal management of traditional transformers becomes a challenge due to their complex geometry. Solenoid type windings transformers also suffer from uneven heat fluxes generated by the magnetic field distribution, which is further exacerbated by the multilayer windings as they impede the flow of heat from winding to winding and winding to ambient surface. The use of planar magnetics mitigates many of these integration challenges while simultaneously yielding more predictable and reliable electromagnetic properties.

In at least one embodiment, a device is a planar inductor. In at least one embodiment, a device is a planar transformer. These are high-frequency high-power planar magnetics. These are the transformer and inductor that are part of the power converter topology. In at least one embodiment, the windings of the components (transformer and inductor) are laid out on the printed circuit board (PCB). In at least one embodiment, a ferrite core is purchased from a third-party vendor with the appropriate parameters (i.e. frequency, permeability). In at least one embodiment, a magnetic component is manufactured using additive manufacturing. In at least one embodiment, a ferrite core is manufactured in a standard size and shape. In at least one embodiment, a planar magnetic device is to keep core and conduction losses within manageable levels without compromising size and weight. Magnetic components may be the largest source of power loss in the power converter.

Without being bound to a particular theory, the concept of “advanced” planar magnetics builds upon the recent developments of general planar magnetics theory to establish an evolved architecture that combines the benefits of planar magnetics and the capabilities of additive manufacturing. Through planar magnetics, components such as transformers and inductors can be more precisely designed, manufactured, and integrated. In addition to an increase in precision, planar magnetics can exhibit inherently improved thermal performance. This improved thermal performance is a result of the high aspect ratio of the planar component windings.

In embodiments of the present invention, the one or more planar windings are often constructed from stacked conductive layers within a multi-layer structure, as is the case in traditional PCBs. The high aspect ratio provides the adequate cross-sectional area for optimal current flow while having large characteristic planes at which heat transfer can occur.

Notwithstanding, it is appreciated that the increased cross-sectional area of a heat transfer plane can be thermally coupled with highly thermally conductive materials. Traditionally, these surfaces are coupled to heatsinks and heat exchangers. These heatsinks and heat exchangers can be additively manufactured. High performance heatsinks and heat exchangers can be designed, manufactured, and integrated using additive manufacturing with geometries that would otherwise be too complex and therefore too expensive through traditional manufacturing methods.

However, the introduction of high aspect ratio conductors amplifies existing effects of electromagnetic coupling such as parasitic resistance, capacitance, and inductance. These parasitics occur when a bulk conductor is placed near an active component trace. Parasitics such as eddy currents and biplanar capacitance are a direct result of electromagnetic field coupling created by an active circuit in combination with the physical geometry of affected conductors and insulators. This electromagnetic coupling is often undesirable and significant efforts are often made to reduce their impact. By thermally coupling these heat transfer planes, significant parasitics are induced. Using geometries only capable through additive manufacturing, these parasitics can be accurately and precisely modified.

These mechanical geometries created through additive manufacturing can be analytically modelled and combined with the electromagnetic considerations of the magnetic component and its circuit. This electro-thermo-mechanical integration yields a complex model that equally balances the components circuit properties and the thermal performance. Geometries such as thin-fins, pillars, etc. can be created through additive manufacturing. These structures can then be tweaked in order to induce specific parasitics on the magnetic component, and therefore, it's active circuit performance. This novel coupling of additive manufactured thermal geometries and planar magnetic electrical parasitics can then be leveraged to finely tune the electrical characteristics and thermal performance of transformers and inductors.

In order to leverage this entangled electro-thermo-mechanical relationship between additive manufactured thermal geometries and planar magnetic electrical parasitics, a highly systematic and parallel design methodology is required. An integrated electro-thermo-mechanical approach provides planar magnetics with the precise electrical characteristics and optimal thermal performance with fine tuning capabilities provided by additive manufactured heat transfer geometries.

### Other Embodiments

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the described embodiments in any way. Rather, the foregoing detailed description will provide those skilled in the art with a convenient road map for implementing the exemplary embodiment or exemplary embodiments.

In at least one embodiment, a converter system is installed on a panel with a thermal management in place. For example, a satellite has in place a system to move heat away from sub-modules. In at least one embodiment, a converter unit will then be mounted on the spacecraft and a TMS will ensure the heat is moved away from its internal components towards the spacecraft, which in turn has its own system to continue moving heat away from the spacecraft. Similar operation for all other applications such as electric vehicles.

Further, while aspects of the present invention were discussed as applied to a high power circuit-board, and to a vapor chamber, the present invention is not so limited. Aspects of the present invention could be equally applied to other heat transfer applications. Such use is within the scope of the present invention and contemplated by the following initial claim.

The foregoing description is illustrative of particular embodiments of the invention, but is not meant to be a limitation upon the practice thereof. The following claims, including all equivalents thereof, are intended to define the scope of the invention.

1. A modular isolated power converter, the power converter comprising:
an LLC power converter circuit comprising at least one switching bridge, an LLC tank circuit, and at least one transformer and rectifier circuit; and
at least one thermal management solution (TMS) mounted to one or more components of said LLC power converter circuit;
wherein said TMS is mounted to one or more components of said LLC power converter circuit for removal of heat generated by said LLC power converter circuit while in operation.

2. The power converter of claim 1, wherein said at least one switching bridge is at least one power transistor.

3. The power converter of claim 2, wherein said at least one power transistor is at least one Gallium Nitride power transistor (GaN).

4. The power converter of claim 1, wherein said at least one transformer and rectifier circuit comprises at least one planar magnetic transformer.

5. The power converter of claim 1 wherein said TMS further comprises a vapor chamber, said vapor chamber comprising:
a top finned radiator structure 10; and
a case chamber 20.

6. The power converter of claim 5 wherein said case chamber comprises:
an outer layer 30 that is physically and thermally coupled through a top surface of a top portion 35 of the outer layer 30 to said finned radiator structure 10, wherein a bottom surface of a bottom portion 85 of the outer layer is physically and thermally coupleable to at least a first heat source component 97;
an inner wicking layer 40 that is physically and thermally coupled to the outer layer 30;
a bottom portion 75 of an inner wicking layer 40, comprising a 60 plurality of capillary pathways; and
a pair of the capillary pathways forming the sides of a substantially trapezoidal nonrectangular region in a direction of capillary flow, wherein the plurality of capillary pathways conduct liquid to a designated customized region 70.

7. A modular isolated power converter, the power converter comprising:
an LLC power converter circuit comprising at least one switching bridge, an LLC tank circuit, and at least one transformer and rectifier circuit; and
at least one thermal management solution (TMS) mounted to one or more components of said LLC power converter circuit;
wherein said TMS is mounted to one or more components of said LLC power converter circuit for removal of heat generated by said LLC power converter circuit while in operation;
wherein said TMS further comprises a vapor chamber, said vapor chamber comprising:
a top finned radiator structure 10; and
a case chamber 20 comprising:
an outer layer 30 that is physically and thermally coupled through a top surface of a top portion 35 of the outer layer 30 to said finned radiator structure 10, wherein a bottom surface of a bottom portion 85 of the outer layer is physically and thermally coupleable to at least a first heat source component 97;
an inner wicking layer 40 that is physically and thermally coupled to the outer layer 30;
a bottom portion 75 of an inner wicking layer 40, comprising a 60 plurality of capillary pathways; and
a pair of the capillary pathways forming the sides of a substantially trapezoidal nonrectangular region in a direction of capillary flow, wherein the plurality of capillary pathways conduct liquid to a designated customized region 70.

8. A method for providing a modular isolated power converter, the method comprising:
use of at least one power transistor as a switching bridge;
use of at least one transformer and rectifier circuit; and
use of at least one thermal management solution (TMS) mounted to one or more of said power transistor, transformer and rectifier circuit, or combinations thereof.

9. The method of claim 8 wherein said at least one power transistor is at least one Gallium Nitride power transistor (GaN)

10. The method of claim 8, wherein said at least one transformer and rectifier circuit comprises at least one planar magnetic transformer.
